(19) United States
(12) Patent Application Publication
(10) Pub. No.: US 2026/0266562 A1
(43) Pub. Date: Sep. 10, 2026

(54) HEAT RECLAMATION MULTIPLE WASTE TANKS AT EACH STAGE

(71) Applicant: TOKYO ELECTRON LIMITED, Tokyo (JP)

(72) Inventors: Peter DELIA, Albany, NY (US); Ronald NASMAN, Albany, NY (US); James GROOTEGOED, Albany, NY (US); Norman JACOBSON, Albany, NY (US); Isabella DIAZ, Albany, NY (US)

(73) Assignee: TOKYO ELECTRON LIMITED, Tokyo (JP)

(21) Appl. No.: 19/073,349

(22) Filed: Mar. 7, 2025

(51) Int. Cl. F28D 21/00; F28D 20/00; F28D 20/02; H01L 21/67; H01L 21/677

(52) U.S. Cl. CPC F28D 21/0001; F28D 20/003; F28D 20/02; H10P 72/0452; H10P 72/0602; H10P 72/38; F28D 2020/0008; F28D 2020/0078; F28D 2021/0052

(57) ABSTRACT

Aspects of the present disclosure provide a system for storing hot/cold waste generated during some processing steps in a wafer processing system and providing the stored hot/cold waste during next processing steps. For example, the system can include one or more hot waste tanks configured to store hot waste generated from the wafer processing system, one or more waste mixing tanks configured to mix the hot waste stored in the hot waste tanks with cold waste and output mixed hot/cold waste, a first heat exchanger thermally coupled between the hot waste tanks and the waste mixing tanks and configured to transfer the hot waste stored in the hot waste tanks to the waste mixing tanks, and a second heat exchanger thermally coupled to the waste mixing tanks and configured to transfer the mixed hot/cold waste to a next stage.

### FIELD OF THE INVENTION

The present disclosure relates to semiconductor processing, and, in particular, to heat reclamation multiple waste tanks.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor fabrication involves multiple varied steps and processes. One typical fabrication process is known as photolithography (also called microlithography). Photolithography uses radiation, such as ultraviolet or visible light, to generate fine patterns in a semiconductor device design. Many types of semiconductor devices, such as diodes, transistors, and integrated circuits, can be constructed using semiconductor fabrication techniques including photolithography, etching, film deposition, surface cleaning, metallization, and so forth.

Energy collection and storage has played a crucial role in renewable energy technology systems. Thermal energy storage (TES) is proposed to stock thermal energy by heating or cooling a storage medium so that the stored energy can be used at a later time for various heating and cooling applications.

### SUMMARY

Aspects of the present disclosure provide a system for storing hot/cold waste generated during some processing steps in a wafer processing system and providing the stored hot/cold waste during next processing steps. For example, the system can include one or more hot waste tanks configured to collect and store hot waste generated from a wafer processing system, one or more waste mixing tanks configured to mix the hot waste stored in the one or more hot waste tanks with cold waste and output mixed hot/cold waste, a first heat exchanger thermally coupled between the one or more hot waste tanks and the one or more waste mixing tanks and configured to transfer the hot waste stored in the one or more hot waste tanks to the one or more waste mixing tanks, and a second heat exchanger thermally coupled to the one or more waste mixing tanks and configured to transfer the mixed hot/cold waste to a next stage.

In an embodiment, the one or more hot waste tanks can include a first hot waste tank and a second hot waste tank, the first hot waste tank is filled with the hot waste completely, and the first heat exchanger can be configured to transfer the hot waste stored in the first hot waste tank to the one or more waste mixing tanks. In some embodiments, the second hot waste tank is not filled with the hot waste completely, and the first heat exchanger does not transfer the hot waste stored in the second hot waste tank to the one or more waste mixing tanks.

In an embodiment, the one or more waste mixing tanks can include a first waste mixing tank and a second waste mixing tank, and the second heat exchanger can be configured to transfer the mixed hot/cold waste in one of the first waste mixing tank and the second waste mixing tank to the next stage. In some embodiments, the mixed hot/cold waste can be controlled to be at a target temperature. In various embodiments, at least one of the first heat exchanger and the second heat exchanger can be made of metal, such as stainless steel or Hastelloy, with a coating formed thereon to protect from leaching.

In an embodiment, the one or more hot waste tanks can include at least one of a sensible heat storage (SHS) tank, a latent-heat or phase-change storage tank and a chemical energy storage tank. In some embodiments, the one or more hot waste tanks includes the SHS tank with a storage medium contained therein that is configured to be heated by the hot waste. In an embodiment, the storage medium can include a fluid medium. For example, the fluid medium can include water. As another example, the fluid medium can include air. In another embodiment, the storage medium can include a solid medium. For example, the solid medium can include sand. As another example, the solid medium can include cast iron.

In an embodiment, at least one of the first heat exchanger and the second heat exchanger include a concentric tubes heat exchanger. For example, the concentric tubes heat exchanger can be in a parallel-flow arrangement. As another example, the concentric tubes heat exchanger can be in a counterflow arrangement. In another example, at least one of the first heat exchanger and the second heat exchanger can include a cross-flow heat exchanger. For example, the cross-flow heat exchanger can include a finned tubular heat exchanger. As another example, the cross-flow heat exchanger can include a finless tubular heat exchanger.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 is a plan view of an exemplary wafer processing system for fabricating a semiconductor structure according to some embodiments of the present disclosure; and

FIG. 2 is a functional block diagram of an exemplary system that can collect and store hot/cold waste generated during a micro fabrication processing step and provide the stored hot/cold waste for subsequent use during a next micro fabrication processing step according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

According to the present disclosure, a system is proposed that can collect and store hot/cold waste generated during a micro fabrication processing step in a wafer processing system and provide the stored hot/cold waste for subsequent use during a next micro fabrication processing step. The hot/cold waste can be timed and handled in a heat reclamation cabinet. For example, multiple waste tanks can be provided before heat exchangers to allow to time the waste stream with the incoming supply and push the waste through the heat exchangers.

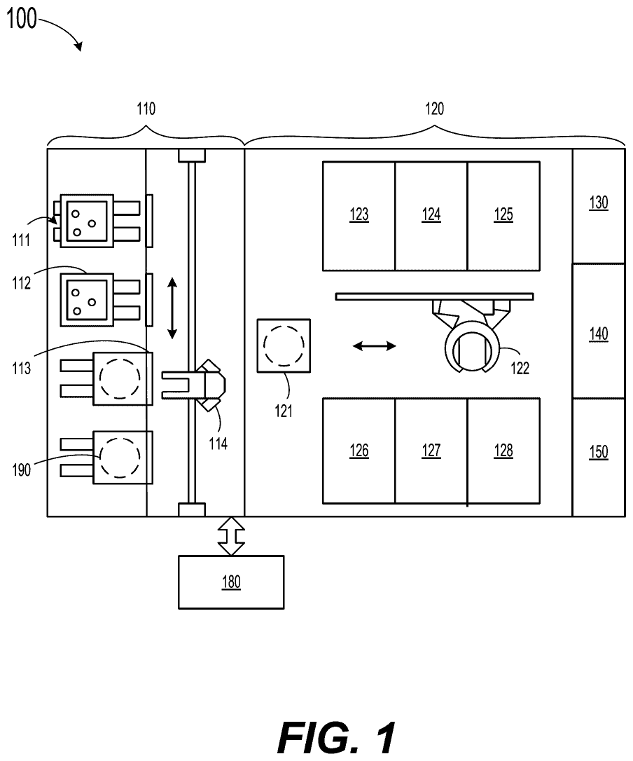

FIG. 1 is a plan view of an exemplary wafer processing system 100 for fabricating a semiconductor structure according to some embodiments of the present disclosure. The wafer processing system 100 can include various wafer handling components or carriers, along with several stages, e.g., a carrier stage 110 and a treatment stage 120. The carrier stage 110 can include one or more pod assemblies 111 that are configured to receive one or more wafer cassettes 112 that are configured to contain one or more wafers 190 that are to be processed in the wafer processing system 100. In an embodiment, the wafer 190 can have a frontside (or working) surface and a backside surface opposite to the frontside surface, and the wafer processing system 100 can perform a variety of micro fabrication processing steps to create at least part of a semiconductor device on the working surface of the wafer 190. For example, field-effect transistors (FETs) may be completed or only partially completed on the working surface of the wafer 190. Doors 113 can open to access the wafers 190 contained in the wafer cassettes 112. A carrier transfer robot 114 can move up and down and transfer the wafers 190 from the wafer cassettes 112 to a shelf unit 121 that is installed in the treatment stage 120 for storing the wafers 190 temporarily.

The treatment stage 120 can include a treatment transfer robot 122 and a variety of treatment modules, e.g., treatment modules 123-128, that may be installed in respective chambers. The treatment transfer robot 122 can be configured to access the shelf unit 121 and the treatment modules 123-128 and transfer the wafers 190 among the treatment modules 123-128 for various processing. In an embodiment, the treatment transfer robot 122 can flip and rotate the wafers 190. In some embodiments, the treatment modules 123-128 can include one or more metrology modules 123, which are configured to measure an amount of wafer bow of the wafers 190 and provide bow measurements to the wafer processing system 100. In another embodiment, the treatment modules 123-128 can also include one or more film formation modules 124 that are configured to form one or more films, e.g., a shape control layer, on a surface of the wafer 190 being processed. For example, the film formation module 124 can be configured to deposit the shape control layer on the working surface and/or backside surface of the wafer 190 using chemical vapor deposition, atomic layer deposition, spin-on film deposition process, or other deposition techniques.

In various embodiments, the treatment modules 123-128 can also include one or more bake modules 125 that are configured to bake the wafer 190 to a target temperature. For example, the bake module 125 can bake and stabilize the wafer 190 at 32° C. or 90° C. As another example, the bake module 125 can bake the wafer 190 with a shape control material (e.g., a heat sensitive material) formed thereon using a pattern of heat that corresponds to the bow measurement of the wafer 190, to correct or modify an internal stress of the shape control layer. In some embodiments, the treatment modules 123-128 can also include one or more radiation sources 126 that are configured to project onto different regions of the shape control material radiations of variable intensities that correspond to the bow measurement of the wafer 190. The treatment modules 123-128 can also include a plurality of heating units 127, which can be installed, for example, on a wafer chuck that is used for a wafer to be placed thereon. In an embodiment, the heating units 127 can have an arrangement corresponding to a certain pattern of heat and generate different temperature ranges of heat, and the wafer chuck can thus have a plurality of heating zones that correspond to the certain pattern of heat. Accordingly, the shape control material can be heated in different regions that correspond to the certain pattern of heat and its stresses in the different regions can be modified to become compressive, neutral or tensile.

In an embodiment, the shape control material can include a heat sensitive material, which, when reactive to heat, may have its internal stress modified by the heat generated by the heating units 127 to become compressive, neutral or tensile. In another embodiment, the shape control material can include a photosensitive material, which, when exposed to actinic radiation or light generated by the radiation source 126, can absorb radiation or light in the desired or required energy spectrum and exhibits a chemical/physical reaction that allows applications at different fields.

In some embodiments, the wafer processing system 100 can further include a controller 180. The controller 180 can be a computer processor located within the wafer processing system 100, or located remotely but being in communication with components, e.g., the metrology module 123, the film formation module 124, the bake module 125, the radiation source 126 and the heating units 127 of the wafer processing system 100. In an embodiment, the controller 180 can be configured to control the metrology module 123 to measure the wafer 190 to identify a bow measurement of the wafer 190 (and/or measure a die to identify a bow measurement of the die), receive the bow measurement from the metrology module 123, control the film formation module 124 to form a shape control layer on the backside (or frontside or both) surface of the wafer 190, control the bake module 125 to differentially bake the wafer 190 with the shape control layer formed thereon using a pattern of heat that corresponds to the bow measurement of the wafer 190, control the radiation source 126 to project on different regions of the shape control layer radiations of variable intensities that correspond to the bow measurement of the wafer 190 and/or control the heating units 127 to generate different temperature ranges of heat that correspond to the a certain pattern of heat, to correct or modify the internal stress of the stressor film.

In some embodiments, the wafer processing system 100 can also include other stages or components, e.g., a stepper/scanner 130, a singulation device 140 and a bonding tool 150. In an embodiment, the stepper/scanner 130 can be detached from the treatment stage 120 since the throughput of the stepper/scanner 130 is often many times greater than the throughput of the carrier stage 110 and the treatment stage 120, and thus dedicating the stepper/scanner 130 to a single treatment stage may waste the stepper/scanner's excess throughput capacity. The singulation device 140 can be configured to dice and singulate a wafer, with or without a shape control layer formed thereon, to obtain a plurality of chiplets. The bonding tool 150 can be configured to connect (or join or bond) an integrated chiplet (or die or wafer) with a wafer together in one mechanically stable package. The bonding tool 150 can employ direct wafer bonding (such as fusion bonding and anodic bonding) or wafer bonding with intermediate material (such as solder bonding and eutectic bonding) to bond a wafer/chiplet with a wafer/chiplet. As such, a D2W bonding platform can consist of handling mechanisms and process modules for the chiplet and the wafer.

Hot/cold waste may be generated during some processing steps. For example, the heating units 127, after generating heat to modify the internal stress of the shape control material, may generate hot waste. By contrast, heat may be needed for another processing steps to be performed. For example, the bake module 125 generates heat in order to bake the wafer 190 to a target temperature.

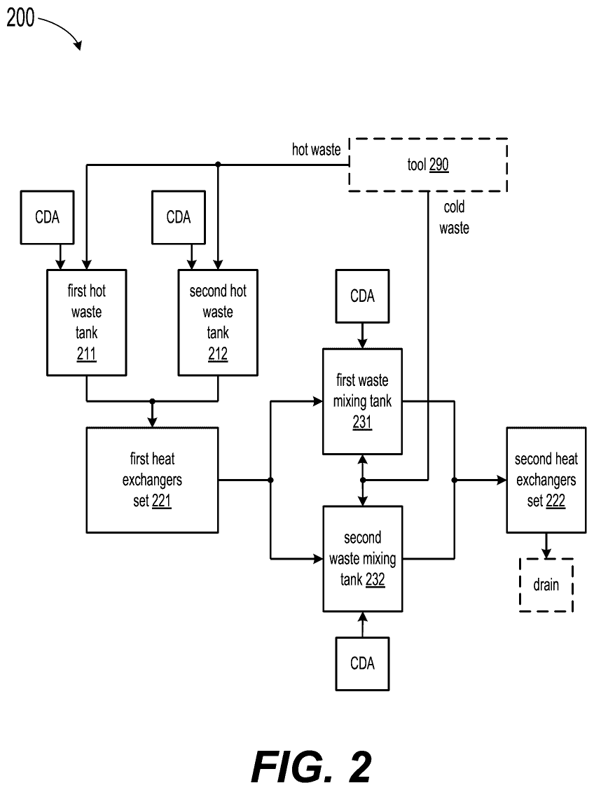

FIG. 2 is a functional block diagram of an exemplary system 200 that can collect and store hot/cold waste generated during some micro fabrication processing steps (e.g., the heating process performed by the heating units 127) in a wafer processing system (e.g., the wafer processing system 100) and provide the stored hot/cold waste for subsequent use during one or more next micro fabrication processing steps (e.g., the baking process performed by the bake module 125) according to some embodiments of the present disclosure. In various embodiments, prior to every set of heat exchangers, there can be multiple waste tanks to contain the waste allowing to time the waste with the supply through the heat exchangers. The multiple waste tanks would be alternatively filled with pressurizing and flowing through the heat exchangers. In some embodiments, there are a set of waste tanks for hot waste and a set of waste tanks for mixing hot and cold waste. Therefore, the need for pump to get past exchangers is eliminated, and, accordingly, perfluoroalkyl and polyfluoroalkyl substances (PFAS) used in tools is reduced, making it a greener option.

In an embodiment, the system 200 can include one or more hot/cold waste storage devices. For example, the hot/cold waste storage devices can include a first hot waste tank 211 and a second hot waste tank 212, each of which can collect and store hot waste, which is generated by a tool 290, e.g., the heating units 127 of the wafer processing system 100. In an embodiment, the first hot waste tank 211 and the second hot waste tank 212 can include a sensible heat storage (SHS) tank, a latent-heat or phase-change storage tank, and/or a chemical energy storage tank, which may differ from one another in terms of capacity, power, efficiency, storage period, and charge and discharge time. With regard to SHS, the amount of heat stored may be determined by the specific heat of a storage medium used in the SHS, the temperature change of the storage medium, and the amount of the storage medium. The storage medium can include a fluid medium (e.g., air and water) and a solid medium (e.g., sand and cast iron). In some embodiments, the first hot waste tank 211 and the second hot waste tank 212 would be alternatively filled with pressurizing and flowing through the heat exchangers. For example, after the first hot waste tank 211 is completely filled with hot waste, the second hot waste tank 212 can be controlled to collect and store the hot waste that is generated thereafter. Accordingly, only the storage medium used in the first hot waste tank 211 can be pressured by compressed dry air (CDA) and flow to a heat exchanger, while the second hot waste tank 212 is still storing the incoming hot waste.

In an embodiment, the system 200 can further include a first heat exchanger (or a first heat exchangers set) 221 that is thermally coupled to the hot/cold storage devices and configured to transfer the hot/cold waste stored therein to a next stage. For example, the first heat exchanger 221 can be coupled to the first hot waste tank 211 and the second hot waste tank 212, and is controlled to transfer the heat stored in one or more of the heat storage devices that are already filled with the hot waste completely, e.g., the first hot waste tank 211, to the next stage, while leaving the second hot waste tank 212 to be still storing the incoming hot waste. In some embodiments, the first heat exchanger 221 can be made of metal, such as stainless steel or Hastelloy, with a coating formed thereon to protect from leaching.

In an embodiment, the first heat exchanger 221 can include a concentric tubes heat exchanger. For example, the concentric tubes heat exchanger can be in a parallel-flow arrangement, in which hot and cold fluids enter at the same end, flow in the same direction, and leave at the same end. As another example, the first heat exchanger 221 can be in a counterflow arrangement, in which hot and cold fluids flow in opposite directions. In another embodiment, the first heat exchanger 221 can include a cross-flow heat exchanger. For example, the cross-flow heat exchanger can be a finned tubular heat exchanger in which the fluids flowing over the tubes are unmixed. As another example, the cross-flow heat exchanger can be a finless tubular heat exchanger in which the fluids flowing over the tubes are mixed.

In an embodiment, the system 200 can further include one or more hot/cold waste mixing tanks, e.g., a first waste mixing tank 231 and a second waste mixing tank 232, that are thermally coupled to the first heat exchanger 221 and configured to mix the heat transferred from the first heat exchanger 221 with cold waste and output mixed hot/cold waste that can be controlled to be at a desired temperature, e.g., 32° C. or 90° C., to a heat exchanger. In some embodiments, the cold waste can be stored in a cold tank first and then transferred by a cold exchanger to either or both of the first waste mixing tank 231 and the second waste mixing tank 232 to be mixed with the heat transferred from the first heat exchanger 221.

In an embodiment, the system 200 can further include a second heat exchanger (or a second heat exchangers set) 222 that is thermally coupled to the first waste mixing tank 231 and the second waste mixing tank 232 and configured to transfer the mixed hot/cold waste stored in either of both of the first waste mixing tank 231 and the second waste mixing tank 232 to a next stage, e.g., the bake module 125.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A system, comprising:
one or more hot waste tanks configured to collect and store hot waste generated from a wafer processing system;
one or more waste mixing tanks configured to mix the hot waste stored in the one or more hot waste tanks with cold waste and output mixed hot/cold waste;
a first heat exchanger thermally coupled between the one or more hot waste tanks and the one or more waste mixing tanks, the first heat exchanger configured to transfer the hot waste stored in the one or more hot waste tanks to the one or more waste mixing tanks; and
a second heat exchanger thermally coupled to the one or more waste mixing tanks, the second heat exchanger configured to transfer the mixed hot/cold waste to a next stage.

2. The system of claim 1, wherein the one or more hot waste tanks include a first hot waste tank and a second hot waste tank, the first hot waste tank is filled with the hot waste completely, and the first heat exchanger is configured to transfer the hot waste stored in the first hot waste tank to the one or more waste mixing tanks.

3. The system of claim 2, wherein the second hot waste tank is not filled with the hot waste completely, and the first heat exchanger does not transfer the hot waste stored in the second hot waste tank to the one or more waste mixing tanks.

4. The system of claim 1, wherein the one or more waste mixing tanks include a first waste mixing tank and a second waste mixing tank, and the second heat exchanger is configured to transfer the mixed hot/cold waste in one of the first waste mixing tank and the second waste mixing tank to the next stage.

5. The system of claim 1, wherein the mixed hot/cold waste is controlled to be at a target temperature.

6. The system of claim 1, wherein at least one of the first heat exchanger and the second heat exchanger is made of metal with a coating formed thereon to protect from chemistry and/or prevent leaching.

7. The system of claim 6, wherein the metal includes stainless steel or Hastelloy.

8. The system of claim 1, wherein the one or more hot waste tanks include at least one of a sensible heat storage (SHS) tank, a latent-heat or phase-change storage tank and a chemical energy storage tank.

9. The system of claim 8, wherein the one or more hot waste tanks includes the SHS tank with a storage medium contained therein that is configured to be heated by the hot waste.

10. The system of claim 9, wherein the storage medium includes a fluid medium.

11. The system of claim 10, wherein the fluid medium includes water.

12. The system of claim 10, wherein the fluid medium includes air.

13. The system of claim 9, wherein the storage medium includes a solid medium.

14. The system of claim 13, wherein the solid medium includes cast iron.

15. The system of claim 1, wherein at least one of the first heat exchanger and the second heat exchanger include a concentric tubes heat exchanger.

16. The system of claim 15, wherein the concentric tubes heat exchanger is in a parallel-flow arrangement.

17. The system of claim 15, wherein the concentric tubes heat exchanger is in a counterflow arrangement.

18. The system of claim 1, wherein at least one of the first heat exchanger and the second heat exchanger include a cross-flow heat exchanger.

19. The system of claim 18, wherein the cross-flow heat exchanger includes a finned tubular heat exchanger.

20. The system of claim 18, wherein the cross-flow heat exchanger includes a finless tubular heat exchanger.
